(19) United States
(12) Patent Application Publication
(10) Pub. No.: US 2012/0297704 A1
(43) Pub. Date: Nov. 29, 2012

(54) Alternative energy structure

(75) Inventor: Alex P. Glynn, Orlando, FL (US)

(73) Assignee: Kenergy Development Corp.

(21) Appl. No.: 13/068,887

(22) Filed: May 23, 2011

(51) Int. Cl. E04B 1/34; E04H 14/00; E04B 1/343; H01L 31/052

(52) U.S. Cl. 52/173.3; 136/246; 52/173.1

(57) ABSTRACT

An alternative energy structure is disclosed, defined by an upper section and a lower section, wherein at least part of the upper section is solar transparent. A panel track traverses the upper section and a counterweight track traverses the lower section. The tracks are non-horizontal. A solar panel is movably connected to the panel track, and a counterweight is movably connected to the counterweight track such that the panel can traverse the upper section and the counterweight can traverse the lower section. The solar panel and the counterweight are connected to one another by a first connection mechanism and an opposite, second connection mechanism. A drive motor is connected to at least one of: the solar panel, the counterweight, the first connection mechanism and the second connection mechanism, to drive the solar panel from a first position to an opposite, second position to follow the sun.

### BACKGROUND OF INVENTION

a. Field of Invention

The invention relates generally to solar energy, and especially to the generation of useful electricity from solar energy. More specifically, the present invention relates to movable solar panels that track the sun.

b. Description of Related Art

The following patents are representative of the field pertaining to the present invention:

U.S. Pat. No. 5,149,351 to Susumu Yaba et al. describes a method of making a curved glass surface with a solar panel formed thereon. A window for an automobile, especially for a sunroof is formed by heating a glass sheet from 500° to 600° C. A transparent electroconductive film is then formed on one side, such as by a CVD method and bending the sheet with the film after heating the temperature from 580° to 650° C.

U.S. Pat. No. 7,081,810 B2 to Jack V. Henderson et al. describes a roof rack assembly for transporting articles along a roof of a motor vehicle that includes a frame member extending along the roof. The roof rack assembly also includes an electronic component for receiving and transmitting signals to an interior portion of the motor vehicle.

U.S. Pat. No. 7,677,242 B2 to Giacomo Carcangiu et al. describes a solar-panel unit with: an attachment structure; at least one solar panel, which is delimited by an extensive plane surface of incidence of the solar radiation and is connected to the attachment structure; and a hinging assembly, set between the attachment structure and the solar panel, to enable rotation of the solar panel with respect to the attachment structure about an inclined hinge axis forming an angle smaller than 90° with a horizontal plane.

U.S. Pat. No. 7,705,978 B2 to Mau-Song Chou et al. describes a technique for providing high-contrast images of defects in solar cells and solar panels, by illuminating each cell under inspection with broadband infrared radiation, and then forming an image of radiation that is secularly reflected from the cell. Multi junction solar cells have a metal backing layer that secularly reflects the illumination back into an appropriately positioned and aligned camera, selected to be sensitive to infrared wavelengths at which the solar cell materials are relatively transparent.

U.S. Pat. No. 7,793,654 B1 to Anthony R Thorne describes a solar tracking system comprising a support base, and a panel mounting section mounted to the support base for rotation about a generally vertical axis of rotation. The panel is mounted to the mounting section to be able to rotate about a generally horizontal secondary panel axis of rotation. There is a panel positioning section comprising a base positioning section and an intermediate positioning section having a rear connecting portion to contact the base connecting region and a forward connecting positioning location to connect to the panel at a forward panel connecting positioning location. The intermediate positioning section has a linking axis extending between the rear connecting positioning location and the panel connecting location. The panel is rotated about the main axis of rotation and the intermediate positioning section changes its angular position relative to the base positioning section to cause the tilt angle of the panel to change to track the sun. The positioning section can have its connecting location(s) adjusted to be adapted to both summer and winter conditions so that it is possible to maintain the panel in the proper orientation.

U.S. Pat. No. 7,832,892 B2 to Xin-Jian Xiao et al. describes a solar LED lamp assembly that includes a mounting member and two LED lamps fixed to a free end of the mounting member. The mounting member includes a pole and a cylinder canister coupled with a distal end of the pole. The two LED lamps are respectively fixed to two opposite lateral sides of a circumferential periphery the canister of the mounting member and extend across each other. Each LED lamp includes a lamp frame, a plurality of LED modules mounted in the lamp frame and a solar panel mounted over a top of the lamp frame. The solar panel receives solar energy and converts it into electrical energy to activate the LED modules to radiate light.

Notwithstanding the prior art, the present invention is neither taught nor rendered obvious thereby.

### SUMMARY OF INVENTION

The present invention is directed to an alternative energy structure. It includes a cylindrical outer structure having its centerline in a substantially horizontal position and being defined by an upper section and a lower section, with opposing sides wherein at least a portion of said upper portion is solar transparent. At least one non-horizontal panel track traverses the upper section of the outer structure within the outer structure. At least one solar panel is movably connected to the panel track so as to be traversable from one side of the upper section to an opposite side of the upper section. At least one non-horizontal counterweight track traverses the lower portion of the outer structure within the outer structure. At least one counterweight is movably connected to the counterweight track so as to be traversable from one side of the lower section to an opposite side of the lower section. The at least one solar panel and the at least one counterweight are connected to one another by a first connection mechanism and by an opposite, second connection mechanism. A drive motor is connected to at least one of the following: the at least one solar panel, the at least one counterweight, the first connection mechanism, and the second connection mechanism, to drive the at least one solar panel from a first position to an opposite second position to follow the sun.

In some preferred embodiments of the present invention alternative energy structure, the alternative energy structure has at least a portion of the upper section being a solar transparent material selected from the group consisting of glass, plastic, and combinations thereof.

In some preferred embodiments of the present invention alternative energy structure, the drive motor includes a processor for controlling speed, direction, and timing of the drive motor to cause the at least one solar panel to track the sun.

In some preferred embodiments of the present invention alternative energy structure, the at least one solar panel is an array of horizontally connected solar panels.

In some preferred embodiments of the present invention alternative energy structure, the cylindrical structure is a cylindrical greenhouse.

In some preferred embodiments of the present invention alternative energy structure, at least a majority of said cylindrical structure lower section is subterranean.

In some different preferred embodiments of the present invention alternative energy structure, the building's outer structure is defined by an upper section, at least one wall, connected to the upper section, and a lower section, connected to the at least one wall. The upper section has a first side and an opposite side, and the lower section has a first side and an opposite side. At least a portion of the upper section is solar transparent. At least one non-horizontal panel track traverses the upper section of the outer structure. At least one solar panel is movably connected to the track so as to be traversable from the first side of the upper section to the opposite side of the upper section. At least one non-horizontal counterweight track traverses the lower section of the outer structure, within the outer structure. At least one counterweight is movably connected to the counterweight track so as to be traversable from the first side of the lower section to the opposite side of the lower section. The at least one solar panel and the at least one counterweight are connected to one another by a first connection mechanism and by an opposite, second connection mechanism. A drive motor is connected to at least one of the following: the at least one solar panel, the at least one counterweight, the first connection mechanism, and the second connection mechanism.

In some preferred embodiments of the present invention alternative energy structure in which the building's outer structure is defined by an upper section, at least one wall, connected to the upper section, and a lower section, connected to the at least one wall, at least a portion of the upper section is a solar transparent material selected from the group consisting of glass, plastic, and combinations thereof.

In some preferred embodiments of the present invention alternative energy structure in which the building's outer structure is defined by an upper section, at least one wall, connected to the upper section, and a lower section, connected to the at least one wall, the drive motor includes a processor for controlling the speed, direction; and timing of the drive motor to cause the at least one solar panel to track the sun.

In some preferred embodiments of the present invention alternative energy structure in which the building's outer structure is defined by an upper section, at least one wall, connected to the upper section, and a lower section, connected to the at least one wall, the at least one solar panel is an array of horizontally connected solar panels.

In some preferred embodiments of the present invention alternative energy structure in which the building's outer structure is defined by an upper section, at least one wall, connected to the upper section, and a lower section, connected to the at least one wall, the at least one non-horizontal panel track and the at least one non-horizontal counterweight track define paths selected from the group consisting of: circular, elliptical, arcuate, polygonal, and combinations of these.

In some preferred embodiments of the present invention alternative energy structure in which the building's outer structure is defined by an upper section, at least one wall, connected to the upper section, and a lower section, connected to the at least one wall, the first connection mechanism is a plurality of connection mechanisms, and the second connection mechanism is a plurality of connection mechanisms.

In some preferred embodiments of the present invention alternative energy structure in which the building's outer structure is defined by an upper section, at least one wall, connected to the upper section, and a lower section, connected to the at least one wall, the first connection mechanism and the second connection mechanism drive the at least one solar panel at a rate selected from the group consisting of: continuous, periodic, incremental, and combinations of these.

In some preferred embodiments of the present invention alternative energy structure in which the building's outer structure is defined by an upper section, at least one wall, connected to the upper section, and a lower section, connected to the at least one wall, the upper section of the building outer structure is selected from the group consisting of: cylindrical, polygonal prismatic, polyhedral, and combinations of these.

In some different preferred embodiments of the present invention alternative energy structure, the non-horizontal panel track and the non-horizontal counterweight track are not included. An outer structure is defined by an upper section and a lower section. The upper section has a first side and an opposite side, the lower section has a first side and an opposite side. A first connection mechanism is movably attached to the outer structure. A second connection mechanism is movably attached to the outer structure. At least one solar panel is connected to the first connection mechanism and the second connection mechanism such that the at least one solar panel is movable between the first side and the opposite side of the upper section. At least one counterweight is connected to the first connection mechanism and the second connection mechanism such that the at least one counterweight is movable between the first side and the opposite side of the lower section. A drive motor is connected to at least one of the following: the at least one solar panel, the at least one counterweight, the first connection mechanism, and the second connection mechanism, to drive the at least one solar panel from the first side of the upper section to the opposite side of the upper section to follow the sun.

In some preferred embodiments of the present invention alternative energy structure in which the non-horizontal panel track and the non-horizontal counterweight track are not included, at least a portion of the upper section is a solar transparent material selected from the group consisting of glass, plastic, and combinations thereof.

In some preferred embodiments of the present invention alternative energy structure in which the non-horizontal panel track and the non-horizontal counterweight track are not included, the drive motor includes a processor for controlling the speed, direction, and timing of the drive motor to cause the at least one solar panel to track the sun.

In some preferred embodiments of the present invention alternative energy structure in which the non-horizontal panel track and the non-horizontal counterweight track are not included, the at least one solar panel is an array of horizontally connected solar panels.

In some preferred embodiments of the present invention alternative energy structure in which the non-horizontal panel track and the non-horizontal counterweight track are not included, the invention further includes an axle bracket connected to the at least one solar panel, an axle rotatably connected to the axle bracket, and at least one wheel connected to the axle such that the at least one solar panel rolls on the at least one wheel.

In some preferred embodiments of the present invention alternative energy structure in which the non-horizontal panel track and the non-horizontal counterweight track are not included, the invention further includes a solar panel axle bracket connected to the at least one solar panel, a counterweight axle bracket connected to the at least one counterweight, a solar panel axle rotatably connected to the solar panel axle bracket, a counterweight axle rotatably connected to the counterweight axle bracket, at least one solar panel wheel connected to the solar panel axle, and at least one counterweight wheel connected to the counterweight axle, such that the at least one solar panel rolls on the at least one solar panel wheel and the at least one counterweight rolls on the at least one counterweight wheel.

Additional features, advantages, and embodiments of the invention may be set forth or apparent from consideration of the following detailed description, drawings, and claims. Moreover, it is to be understood that both the foregoing summary of the invention and the following detailed description are exemplary and intended to provide further explanation without limiting the scope of the invention as claimed.

### BRIEF DESCRIPTION OF THE DRAWINGS

The accompanying drawings, which are included to provide a further understanding of the invention and are incorporated in and constitute a part of this specification, illustrate preferred embodiments of the invention and together with the detailed description serve to explain the principles of the invention. In the drawings:

FIG. 1 is a partial front sectional view of an embodiment of an alternative energy structure according to the present invention;

FIG. 2 is an oblique view of another embodiment of an alternative energy structure according to the present invention;

FIG. 3 is a front sectional view of another embodiment of an alternative energy structure according to the present invention;

FIG. 4 is a front sectional view of another embodiment of an alternative energy structure according to the present invention; and

FIG. 5 is a front sectional view of another embodiment of an alternative energy structure according to the present invention.

FIG. 6 is a front sectional view of another embodiment of the alternative energy structure according to the present invention.

### DETAILED DESCRIPTION OF THE EMBODIMENTS

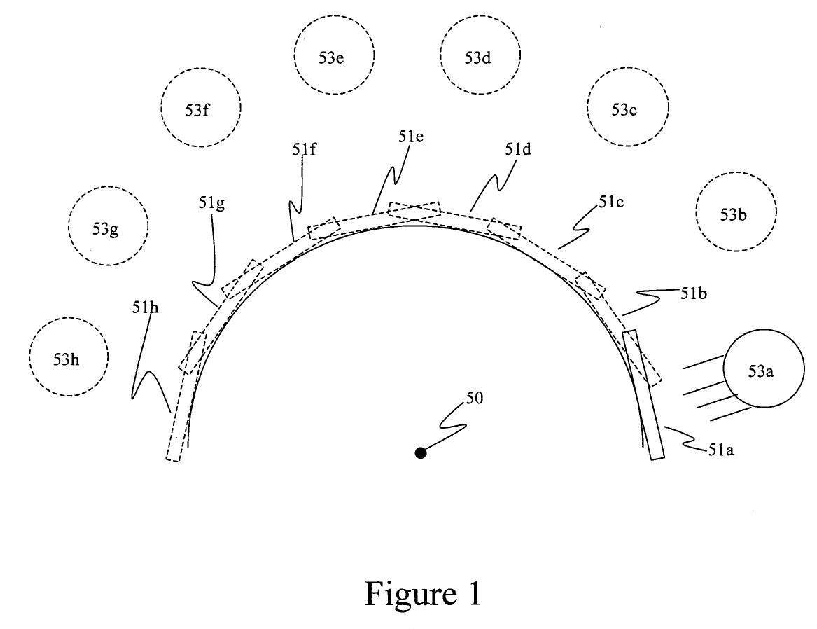

Referring now to the drawings wherein like reference numerals designate corresponding parts throughout the several views, FIGS. 1 through 5 illustrate an alternative energy structure according to the present invention.

Referring to FIG. 1, which depicts one embodiment of the present invention, a building 50 is shown with a cylindrical outer structure. At least one solar panel 51 is movably attached to said building 50 such that the at least one solar panel moves with the sun 53. In FIG. 1, for example, when the sun 53 is at position 53c, the at least one solar panel 51 is at position 51c; when the sun 53 is at position 53f, the at least one solar panel 51 is at position 51f. FIG. 1 shows that as the sun 53 moves, the at least one solar panel 51 tracks it. Thus when the sun 53 is at positions 53a, 53b, 53c, 53d, 53e, 53f, 53g, and 53h, the at least one solar panel 51 is at positions 51a, 51b, 51c, 51d, 51e, 51f, 51g, and 51h, respectively.

Although the path traversed by the solar panel is not horizontal, the solar panel does not have to be flexible. It is possible to design a rigid solar panel that is adapted to run along a curved track or path, as shown in the embodiment illustrated in FIG. 1. The panel itself could be rigid, yet curved, or the panel could be flat and attached to brackets adapted to fit a curve. The invention contemplates and embraces both flexible and rigid solar panels.

It is immaterial to the invention whether, when in operation, the at least one solar panel moves continually, continuously, periodically, or incrementally. Whether the at least one solar panel constantly moves throughout the day, or whether it starts and stops, is not material. In embodiments in which the panel moves constantly while in operation, gears will allow a fairly low-output motor to drive the panels at a relatively slow speed, but with high torque. In other embodiments, the solar panel can stop at certain points during the day. This may be desirable at certain times of the day, such as high noon, when there may be a period of time during which the constant adjustment of the solar panel to face the sun would consume more energy than would be gained by those angle adjustments. If the movement of the at least one solar panel is intermittent, the starting and stopping can be manually controlled, could be set to a timer, or could be governed by the position of the sun. In some embodiments of the invention, the movement of the at least one solar panel is controlled by a computer.

Throughout the detailed description and elsewhere in the application specification and claims, the phrase “solar panel” does not necessarily refer to only a single solar panel. While some embodiments of the invention allow for the use of a single panel, in other embodiments of the invention, the single panel is replaced by an array of horizontally connected solar panels, which run substantially along the length of the building 50.

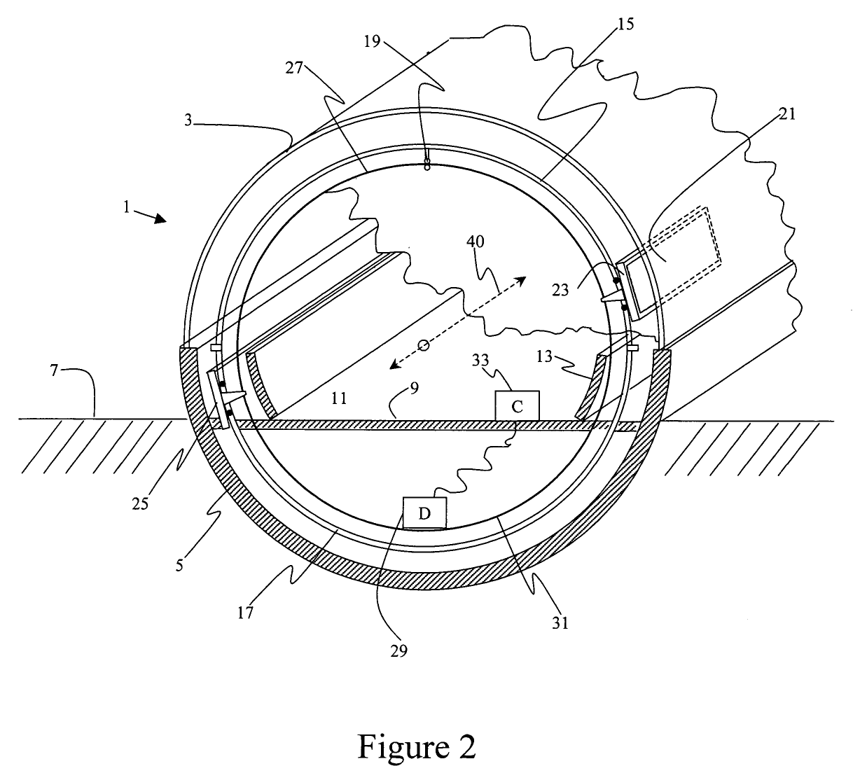

Referring now to FIG. 2, another embodiment of the invention is shown. In this embodiment, the alternative energy structure 1 has a cylindrical outer structure. The cylindrical outer structure shown in FIG. 2 is comprised of an upper section 3, which in this embodiment is made of glass or another suitable transparent material, and a lower section 5, which in this embodiment is made from concrete or another suitable building material. In this embodiment, shown in FIG. 2, part of the alternative energy structure 1 is located above the ground 7, and part of the alternative energy structure 1 is located below the ground 7. In this embodiment, the ground 7 does not precisely bisect the alternative energy structure 1; instead, a portion of the lower section 5 rises above the level of the ground 7. Within the alternative energy structure 1 shown in FIG. 2, there is a floor 9 at the level of the ground 7. This embodiment includes a first wall 11 that runs the length of the alternative energy structure 1, and it includes a second wall 13 that also runs the length of the alternative energy structure 1.

With continued reference to FIG. 2, in this the embodiment of the alternative energy structure 1, there is at least one, but preferably more than one, non-horizontal panel track 15 inside the upper section 3 that is approximately co-axial with the upper section 3 about the axis 40.

With continued reference to FIG. 2, in this embodiment of the alternative energy structure 1, there is at least one, but preferably more than one, non-horizontal counterweight track 17 inside the lower section 5 that is approximately co-axial with the lower section 5 about the axis 40.

With continued reference to the embodiment shown in FIG. 2, there is a connection mechanism support 19 connected to the non-horizontal panel track 15. The connection mechanism support 19 retains a cable such as first connection mechanism 27 such that the cable can move lengthwise through the connection mechanism support 19 but cannot slip off the connection mechanism support 19.

With continued reference to FIG. 2 and the embodiment shown therein, solar panel 21 is attached to solar panel support 23. Solar panel support 23 is movably connected to the non-horizontal panel track 15. In the embodiment shown in FIG. 2, the movable connection is accomplished using wheels. Solar panel support 23 is connected to the first connection mechanism 27 and to the second connection mechanism 31 such that when the first connection 27 and the second connection mechanism move around the building's axis 40, the solar panel support 23 moves along the non-horizontal panel track around the building's axis 40. It should be clear at this point that the solar panel 21, which is firmly attached to the solar panel support 23, also moves around the buildings axis 40.

Similarly, the embodiment in FIG. 2 shows a counterweight 25 that is movably connected to the non-horizontal counterweight track 17. In this embodiment, the movable connection is accomplished using wheels. Counterweight support is connected to the first connection mechanism 27 and to the second connection mechanism 31 such that when the first connection 27 and the second connection mechanism move around the building's axis 40, the solar panel support 23 moves along the non-horizontal panel track around the building's axis 40.

In order to move the first connection mechanism 27 and the second connection mechanism 31, a drive motor 29 is present in the basement of the building in the embodiment shown in FIG. 2. This drive motor 29 moves the second connection mechanism back and forth around the axis 40, which in turn moves the solar panel support 23 and the counterweight support 25 around the axis 40.

In some embodiments of the invention, the solar panel 21 runs the full length of the alternative energy structure 1, which may be considerable. Although the embodiment shown in FIG. 2 shows only one non-horizontal panel track 15, one non-horizontal counterweight track 17, a first connection mechanism 27, a second connection mechanism 31, and a drive motor 29, embodiments of this invention may include an identical or mirror setup at the opposite end of the building to reduce force on track 15, track 17, mechanism 27, mechanism 31, and drive motor 29. Likewise, three, four, five, or more of these combinations could be spaced along the length of solar panel 21 to distribute force among the various tracks, connection mechanisms, and drive motors.

The drive motor 29 is connected to a control system 33; the control system 33 controls the speed, direction, and timing with which the second connection mechanism 31 is moved, thus controlling the speed, direction, and timing with which the solar panel 21 moves and allowing the solar panel 21 to track the sun. The control system 33 may simply consist of an “on” switch (not shown) that causes the drive motor to move the solar panel from one side (east) of the building to another (west) over the course of time when the sun is up (approximately twelve hours). The system could automatically reset after reaching the limit of east-west movement. The control system 33 could also have an emergency “off” switch (not shown) and a “reset” switch to return the system to its starting (eastern) position. The control system 33 is preferably an automatic system controlled by computer hardware, in which the control system 33 contains information about the sunrise and sunset times for a given date at a given latitude.

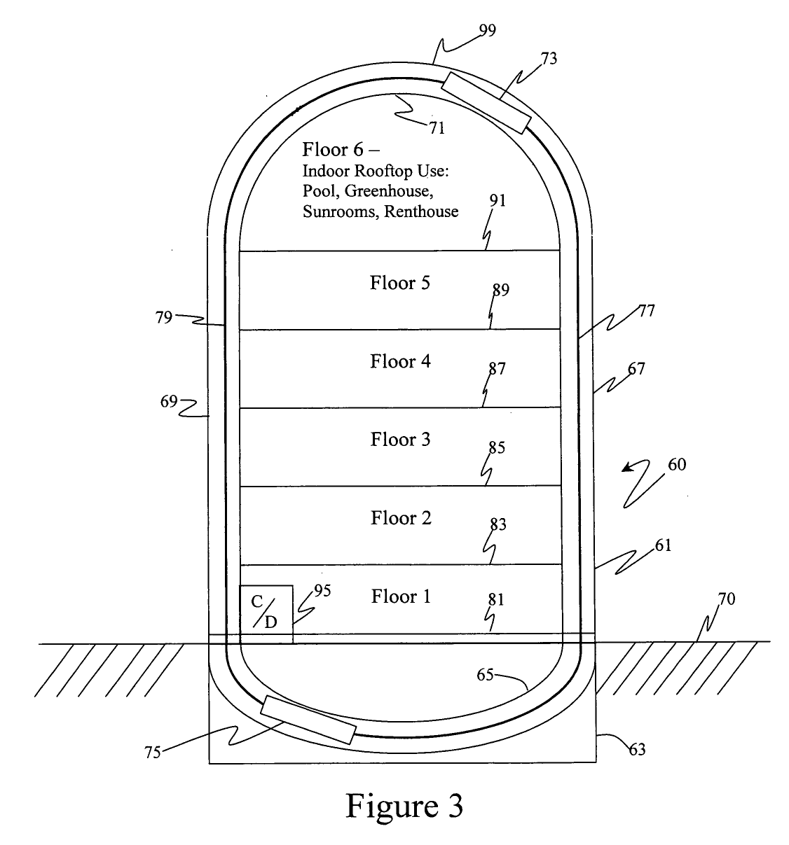

With reference to FIG. 3, another embodiment of the present invention alternative energy structure is shown. In this embodiment, building 60 is the alternative energy structure. It is not material to the invention whether building 60 was originally constructed as an alternative energy structure or whether building 60 was retrofitted as an alternative energy structure. Unlike the embodiments shown in FIGS. 1 and 2, in the embodiment shown in FIG. 3, building 60 is not cylindrical when viewed in cross-section.

Building 60 has an above-ground portion 61 and a below-ground portion 63. The above-ground portion 61 of building 60 has a first wall 67 and an opposite wall 69. First wall 67 and opposite wall 69 support roof 99, at least part of which is solar transparent. Building 60 is shown with six floors, numbered 81 through 91, for the sake of illustration. However, it is immaterial to the invention whether building 60 has many floors, as in a New York City skyscraper, or has no floors, as in a grain silo. In the embodiment shown in FIG. 3, floor 6 91 will have natural sunlight coming through the roof 99, making it suitable for use as a pool, greenhouse, sunrooms, renthouse, or for any other use where sunlight is desired.

Building 60 further contains a non-horizontal counterweight track 65 and a non-horizontal panel track 71. A solar panel 73 is movably connected to the non-horizontal panel track 71. This allows the solar panel 73 to traverse non-horizontal panel track 71 from one side to the other. Likewise, a counterweight 75 is movably connected to the non-horizontal counterweight track 65, which allows the counterweight 75 to traverse non-horizontal counterweight track 65 from one side to the other. Solar panel 73 and counterweight 75 are connected by a first connection mechanism 77 and a second connection mechanism 79. In the embodiment shown in FIG. 3, the drive motor control mechanism 95 is shown on floor 1 81. In this embodiment, control functions are integrated into the drive motor and shown as drive motor control mechanism 95.

In the embodiment shown in FIG. 3, drive motor control mechanism 95 is connected to second connection mechanism 79 such that drive motor control mechanism 95 can control the back-and-forth movement of second connection mechanism 79. With counterweight 75 properly balanced with solar panel 73, relatively little force should be required to move second connection mechanism 79 back and forth.

In the embodiment shown in FIG. 3, first connection mechanism 77 and second connection mechanism 79 are shown within wall 67 and wall 69, respectively. Although certain considerations, such as safety and avoiding exposure to the elements, make it preferable to enclose first connection mechanism 77 and second connection mechanism 79 within wall 67 and wall 69, respectively, it is within the scope of the invention for first connection mechanism 77 and second connection mechanism 79 to be routed on the outside of wall 67 and wall 69, respectively. Another consideration is the weight of the first connection mechanism 77 and the second connection mechanism 79. Assuming that solar panel 73 is fairly heavy, and the counterweight 75 is similarly heavy, cables that run up the wall of a tall building will have to be of strong construction, such as elevator cables, which could be rather heavy. Accordingly, in certain embodiments of the alternative energy structure, it will be necessary to use strong pulleys to support the first connection mechanism 77 and the second connection mechanism 79.

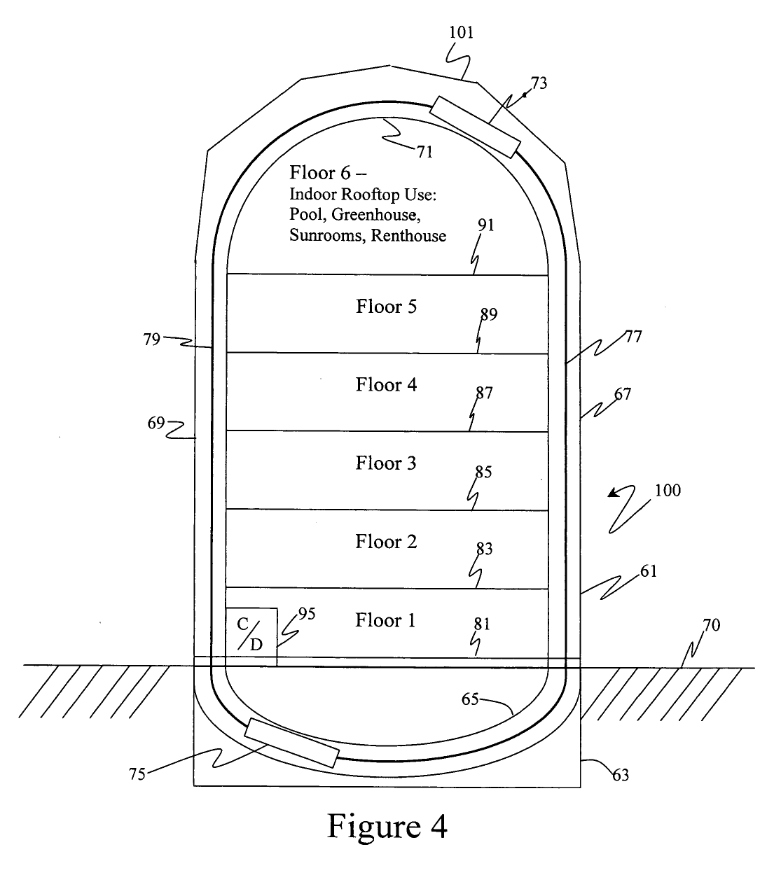

Turning now to FIG. 4, another embodiment of the present invention alternative energy structure is shown. In this embodiment, building 100 has a roof 101 that is not semi-circular when viewed in cross-section. Rather than using curved glass, roof 101 uses plate glass. This illustrates the point that in certain embodiments of the invention, roof 101 is not shaped in the same way as non-horizontal panel track 71. In fact, in various embodiments, roof 101 could be a variety of regular and non-regular shapes. Roof 101 could even be horizontal, as long as there is sufficient clearance to allow the solar panel 73 to traverse the non-horizontal panel track 71. In a similar way, roof 101 does not have to be a regular shape; as long as light can pass through at least part of roof 101, the shape of roof 101 is immaterial.

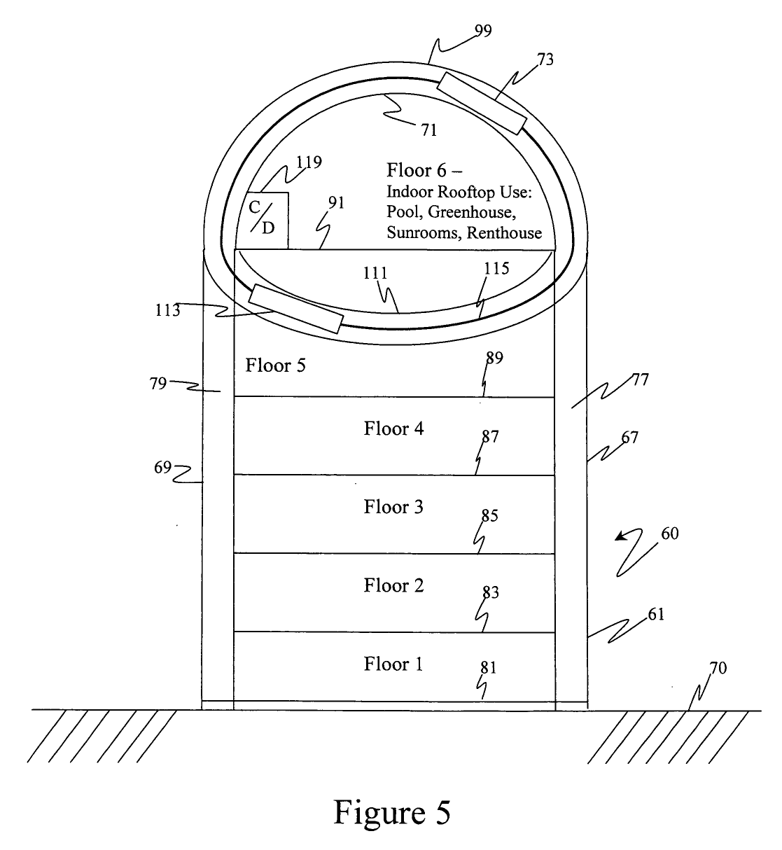

With reference now to FIG. 5, another embodiment of the present invention alternative energy structure is shown. In this embodiment, building 110 has no basement. In this embodiment, non-horizontal counterweight track 111 is located in the penultimate floor 89 of the building.

Like the embodiments shown in FIGS. 3 and 4, building 110 has a first wall 67 and a second wall 69 supporting a roof 99. However, in this embodiment, first connection mechanism 115 and second connection mechanism 117 do not run parallel to the first wall 67 and the second wall 69. Instead, when the alternative energy structure is operating in the forward direction, first connection mechanism 115 passes from the penultimate floor 89 to the top floor 91 near the first wall 67. Likewise, when the alternative energy structure is operating in the forward direction, second connection mechanism 117 passes from the top floor 91 to the penultimate floor 89 near the second wall 69. Obviously, because the first connection mechanism 115 and the second connection mechanism 117 can run in two directions (for example when the system resets itself at night) there are times when the first connection mechanism 115 will pass from the top floor 91 to the penultimate floor 89, and times when the second connection mechanism will pass from the penultimate floor 89 to the top floor 91. It is also important to understand that while FIG. 5 illustrates the combination of solar panel 73, counterweight 113, first connection mechanism 115, and second connection mechanism 117 moving in a counterclockwise direction when in the forward direction, this does not limit the invention. If the building 110 shown in FIG. 5 were viewed from the other end, the combination just described would appear to move in a clockwise direction.

In the embodiment shown in FIG. 5, the drive motor control mechanism 119 is shown on the top floor 91. As in other embodiments, the drive motor control mechanism 119 provides the energy to move the combination of solar panel 73, counterweight 113, first connection mechanism 115, and second connection mechanism 117.

The embodiment in FIG. 5 also illustrates another point: non-horizontal panel track 71 and non-horizontal counterweight track 111 do not have to have the same dimensions. In the embodiment shown in FIG. 5, non-horizontal panel track 71 defines a curve having a smaller diameter than the curve defined by non-horizontal counterweight track 111. Another way to state this is that in the embodiment shown in FIG. 5, non-horizontal panel track 71 and non-horizontal counterweight track 111 are not coaxial. This arrangement would still be functional if the counterweight 113 were to weigh slightly more than the solar panel 73. By having a slightly shallower curve (larger diameter), non-horizontal counterweight track 111 would take up less vertical space than non-horizontal panel track 71. This would allow non-horizontal counterweight track 111 to fit in more confined spaces, such as penultimate floor 89.

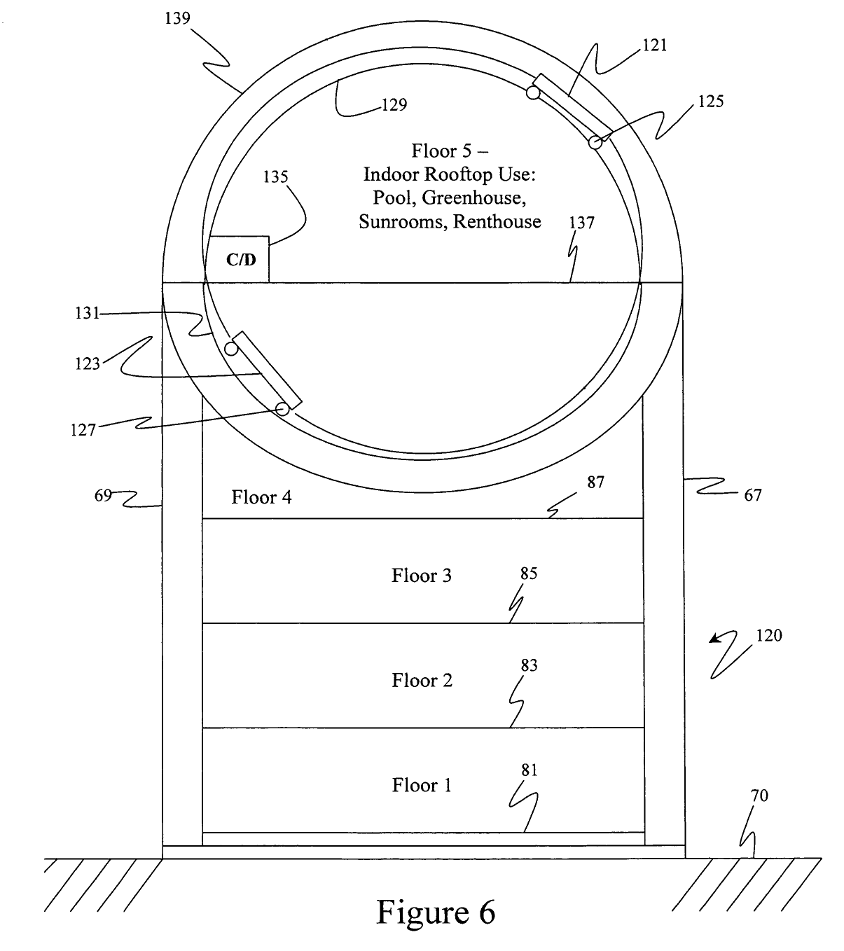

Turning to FIG. 6, another embodiment of the present invention alternative energy structure is shown. In this embodiment, there is no need to have a non-horizontal panel track (71, FIG. 5). Instead, the solar panel 121 could be equipped with at least one wheel 125. The non-horizontal panel track (71, FIG. 5) would be replaced by a non-horizontal panel surface 129. The at least one wheel 125 attached to the solar panel 73 could have pneumatic or solid tires (not shown), and would allow the solar panel 73 to roll across this surface 129. Likewise, the non-horizontal counterweight track (111, FIG. 5) could be replaced in a similar manner by a non-horizontal counterweight surface 131. However, rather than being suspended from the non-horizontal counterweight track (111, FIG. 5), the counterweight 123 would have at least one wheel 127 attached (possibly with tires) and would rest on top of the non-horizontal surface 131. One advantage of using wheels as opposed to tracks is that the non-horizontal surface could then have bends and angles put into it, and the wheels would be better able to traverse the bends and angles than if the panel or the counterweight were on a track.

To summarize, the present invention thus provides an alternative energy structure in which a solar panel is attached to a counterweight, allowing the solar panel to be easily moved throughout the day to track the sun. Although particular embodiments of the invention have been described in detail herein with reference to the accompanying drawings, it is to be understood that the invention is not limited to those particular embodiments, and that various changes and modifications may be effected therein by one skilled in the art without departing from the scope or spirit of the invention as defined in the appended claims.

What is claimed is:

1. An alternative energy structure, which comprises;
(a) a cylindrical outer structure, having its centerline in a substantially horizontal position and being defined by an upper section and a lower section, with opposing sides wherein at least a portion of said upper section is solar transparent;
(b) at least one non-horizontal panel track traversing said upper section of said outer structure within said outer structure;
(c) at least one solar panel moveably connected to said panel track so as to be traversable from one side of said upper section to an opposite side of said upper section;
(d) at least one non-horizontal counterweight track traversing said lower portion of said outer structure within said outer structure;
(e) at least one counterweight moveably connected to said counterweight track so as to be traversable from one side of said lower section to an opposite side of said lower section;
(f) said at least one solar panel and said at least one counterweight being connected to one another by a first connection mechanism and by an opposite, second connection mechanism; and,
(g) a drive motor connected to at least one of: said at least one solar panel, said at least one counterweight, said first connection mechanism and said second connection mechanism, to drive said at least one solar panel from a first position to an opposite second position to follow the sun.

2. The alternative energy structure of claim 1 wherein said alternative energy structure has at least a portion of said upper section being a solar transparent material selected from the group consisting of glass, plastic, and combinations thereof.

3. The alternative energy structure of claim 1 wherein said drive motor includes a processor for controlling speed, direction, and timing of said drive motor to cause said at least one solar panel to track the sun.

4. The alternative energy structure of claim 1 wherein said at least one solar panel is an array of horizontally connected solar panels.

5. The alternative energy structure of claim 1 wherein said cylindrical structure is a cylindrical greenhouse.

6. The alternative energy structure of claim 1 wherein at least a majority of said cylindrical structure lower section is subterranean.

7. An alternative energy structure, which comprises;
(a) a building outer structure, said building outer structure being defined by an upper section, at least one wall, connected to said upper section, and a lower section, connected to said at least one wall, said upper section having a first side and an opposite side, and said lower section having a first side and an opposite side wherein at least a portion of said upper section is solar transparent;
(b) at least one non-horizontal panel track traversing said upper section of said outer structure within said outer structure;
(c) at least one solar panel moveably connected to said track so as to be traversable from said first side of said upper section to said opposite side of said upper section;
(d) at least one non-horizontal counterweight track traversing said lower section of said outer structure within said outer structure;
(e) at least one counterweight moveably connected to said counterweight track so as to be traversable from said first side of said lower section to said opposite side of said lower section;
(f) said at least one solar panel and said at least one counterweight being connected to one another by a first connection mechanism and by an opposite, second connection mechanism; and,
(g) a drive motor connected to at least one of: said at least one solar panel, said at least one counterweight, said first connection mechanism and said second connection mechanism, to drive said at least one solar panel from a first position to an opposite second position to follow the sun.

8. The alternative energy structure of claim 7 wherein at least a portion of said upper section is a solar transparent material selected from the group consisting of glass, plastic, and combinations thereof.

9. The alternative energy structure of claim 7 wherein said drive motor includes a processor for controlling speed, direction, and timing of said drive motor to cause said at least one solar panel to track the sun.

10. The alternative energy structure of claim 7 wherein said at least one solar panel is an array of horizontally connected solar panels.

11. The alternative energy structure of claim 7 wherein said at least one non-horizontal panel track and said at least one non-horizontal counterweight track define paths selected from the group consisting of: circular, elliptical, arcuate, polygonal, and combinations of these.

12. The alternative energy structure of claim 7 wherein said first connection mechanism is a plurality of connection mechanisms, and said second connection mechanism is a plurality of connection mechanisms.

13. The alternative energy structure of claim 7 wherein said first connection mechanism and said second connection mechanism drive said at least one solar panel at a rate selected from the group consisting of: continuous, periodic, incremental, and combinations of these.

14. The alternative energy structure of claim 7 wherein said upper section of said building outer structure is selected from the group consisting of: cylindrical, polygonal prismatic, polyhedral, and combinations of these.

15. An alternative energy structure, which comprises:
(a) an outer structure defined by an upper section and a lower section, said upper section having a first side and an opposite side, said lower section having a first side and an opposite side;
(b) a first connection mechanism movably attached to said outer structure;
(c) a second connection mechanism movably attached to said outer structure;
(d) at least one solar panel connected to said first connection mechanism and said second connection mechanism such that said at least one solar panel is movable between said first side and said opposite side of said upper section;
(e) at least one counterweight connected to said first connection mechanism and said second connection mechanism such that said at least one counterweight is movable between said first side and said opposite side of said lower section; and
(f) a drive motor connected to at least one of: said at least one solar panel, said at least one counterweight, said first connection mechanism, and said second connection mechanism, to drive said at least one solar panel from said first side of said upper section to said opposite side of said upper section to follow the sun.

16. The alternative energy structure of claim 15 wherein at least a portion of said upper section is a solar transparent material selected from the group consisting of: glass, plastic, and combinations thereof.

17. The alternative energy structure of claim 15 wherein said drive motor includes a processor for controlling speed, direction, and timing of said drive motor to cause said at least one solar panel to track the sun.

18. The alternative energy structure of claim 15 wherein said at least one solar panel is an array of horizontally connected solar panels.

19. The alternative energy structure of claim 15 further compromising an axle bracket connected to said at least one solar panel, an axle rotatably connected to said axle bracket, and at least one wheel connected to said axle such that said at least one solar panel rolls on said at least one wheel.

20. The alternative energy structure of claim 15 further compromising a solar panel axle bracket connected to said at least one solar panel, a counterweight axle bracket connected to said at least one counterweight, a solar panel axle rotatably connected to said solar panel axle bracket, a counterweight axle rotatably connected to said counterweight axle bracket, at least one solar panel wheel connected to said solar panel axle, and at least one counterweight wheel connected to said counterweight axle, such that said at least one solar panel rolls on said at least one solar panel wheel and said at least one counterweight rolls on said at least one counterweight wheel.
